(19) United States
(12) Patent Application Publication
(10) Pub. No.: US 2007/0117318 A1
(43) Pub. Date: May 24, 2007

(54) Method of manufacturing NAND flash memory device

(75) Inventor: In No Lee, Kyeongki-do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/593,914

(22) Filed: Nov. 7, 2006

(30) Foreign Application Priority Data
Nov. 18, 2005 (KR) 2005-0110717

(51) Int. Cl. H01L 21/336; H01L 29/76

(52) U.S. Cl. 438/257; 257/314

(57) ABSTRACT

A method of manufacturing a NAND flash memory device, consisting of the steps of consecutively etching a polysilicon layer, a tunnel oxidization layer, and a semiconductor substrate in a polysilicon layer chamber. Accordingly, an etch step and a cleaning step can be reduced, the Turn Around Time (TAT) can be shortened, and additional equipment investment is not required. It is therefore possible to improve productivity and lower cost. Furthermore, the probability that particles may occur is reduced due to a reduction of the etch step. Accordingly, the yield can be improved in mass-production.

### BACKGROUND OF THE INVENTION

1. Field of the Invention

The invention relates, in general, to NAND flash memory devices and, more particularly, to a method of manufacturing a NAND flash memory device, wherein a Turn Around Time (TAT) can be shortened and equipment investment minimized.

2. Related Technology

A cycle test for repeating the read and write operations on NAND flash memory devices of 70 nm or less is typically performed, at which time a current is leaked to a tunnel oxidization layer thinned due to the thinning phenomenon of the tunnel oxidization layer, which is generated in the cell region, thereby hindering data from being properly stored.

To improve the above problem, a Self-Aligned Shallow Trench Isolation (SA-STI) method has been used. A method of manufacturing a NAND flash memory device using the SA-STI method is described below.

A tunnel oxidization layer, a polysilicon layer, a nitride layer, an oxidization layer, an anti-reflection layer, and an organic anti-reflection layer are formed on a semiconductor substrate. The anti-reflection layer is typically formed of SiON. The nitride layer, the oxidization layer and the anti-reflection layer are referred to as a “hard mask layer.” A photoresist is formed on the organic anti-reflection layer. An etch process is then performed to form a photoresist pattern.

In an oxidization layer chamber, the organic anti-reflection layer and the hard mask layer are etched using the photoresist pattern as a mask. The photoresist pattern is then stripped. When the photoresist pattern is stripped, the organic anti-reflection layer is also stripped. A cleaning process is then performed.

While the polysilicon layer is etched in the polysilicon layer chamber using the hard mask layer as a mask, a portion of the anti-reflection layer is stripped. The tunnel oxidization layer is stripped in the oxidization layer chamber using the hard mask layer as a mask. At this time, the anti-reflection layer is all stripped and the oxidization layer is also partially stripped. The semiconductor substrate is etched in the polysilicon layer chamber using the oxidization layer as a mask, thus forming a trench. In this case, the oxidization layer remains to the extent that the nitride layer is not lost.

However, as described above, the oxidization layer, the polysilicon layer, the oxidization layer, and the polysilicon layer are etched in different chambers, and four etch processes are thus required. If a dual trench is to be formed in devices of 70 nm or less in size using this method, a total of eight etch processes are required.

Furthermore, a cleaning process for removing polymer occurring after etching is additionally performed. Accordingly, the TAT becomes very long. Additional etch equipments for the oxidization layer and the polysilicon layer, and additional cleaning equipment are also required. Therefore, there is a high probability that that particles may occur due to the long TAT and the use of several pieces of equipment, resulting in decreased yield in mass-production.

### SUMMARY OF THE INVENTION

Accordingly, the invention addresses the above problems, and discloses a method of manufacturing a NAND flash memory device, in which the TAT can be shortened and equipment investment minimized.

A method of manufacturing a NAND flash memory device according to one aspect of the invention includes the steps of forming a tunnel oxidization layer, a polysilicon layer, a hard mask layer, an organic anti-reflection layer, and a photoresist pattern on a semiconductor substrate, etching the organic anti-reflection layer and the hard mask layer using the photoresist pattern as a mask, and consecutively etching the polysilicon layer, the tunnel oxidization layer and the semiconductor substrate in one chamber using the hard mask layer as a mask, forming a trench.

A method of manufacturing a NAND flash memory device according to another aspect of the invention includes the steps of forming a tunnel oxidization layer, a polysilicon layer, a hard mask layer, an organic anti-reflection layer, and a photoresist pattern on a semiconductor substrate, etching the organic anti-reflection layer and the hard mask layer using the photoresist pattern as a mask, etching the polysilicon layer within a polysilicon layer chamber using the hard mask layer as a mask, etching the tunnel oxidization layer within the polysilicon layer chamber after the polysilicon layer is etched, wherein the tunnel oxidization layer is etched using CHF₃ and Ar gas with source and bias powers being reduced and an oxide layer etch ratio being increased, and etching the semiconductor substrate within the polysilicon layer chamber after the tunnel oxidization layer is etched, thus forming a trench.

### BRIEF DESCRIPTION OF THE DRAWINGS

FIG. 1A to 1C are cross-sectional views illustrating a method of manufacturing a NAND flash memory device according to an embodiment of the invention.

### DESCRIPTION OF SPECIFIC EMBODIMENTS

Specific embodiments according to the invention are described below with reference to the accompanying drawings.

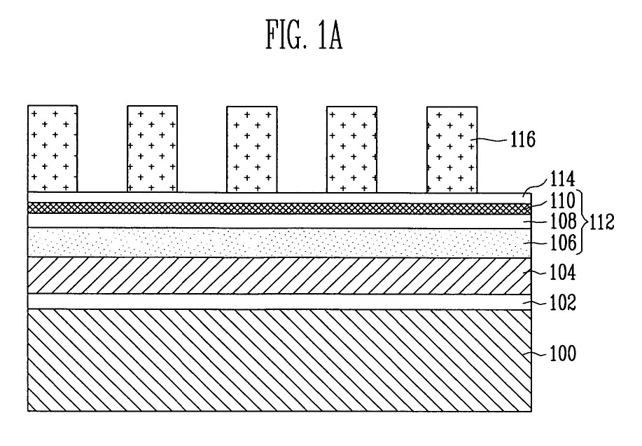

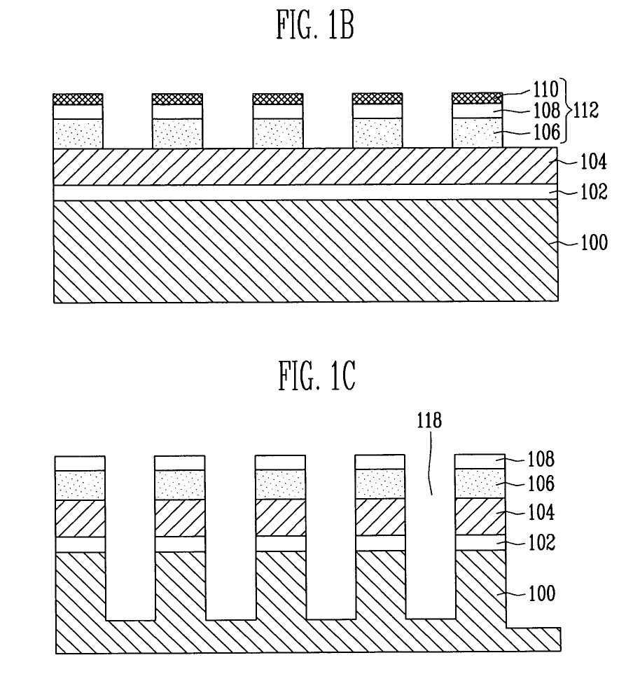

FIG. 1A to 1C are cross-sectional views illustrating a method of manufacturing a NAND flash memory device according to an embodiment of the invention.

Referring to FIG. 1A, a tunnel oxidization layer 102 and a polysilicon layer 104 are formed on a semiconductor substrate 100. A hard mask layer 112 including or consisting of a nitride layer 106, an oxidization layer 108 and an anti-reflection layer 110 is formed on the polysilicon layer 104. The anti-reflection layer 110 is preferably formed using SiON. An organic anti-reflection layer 114 and a photoresist pattern 116 are formed on the anti-reflection layer 110.

Referring to FIG. 1B, an etch process is performed in an oxidization layer chamber using the photoresist pattern 116 as a mask, etching the organic anti-reflection layer 114 and the hard mask layer 112. The photoresist pattern 116 is then stripped. The organic anti-reflection layer 114 is stripped simultaneously when the photoresist pattern 116 is stripped. A cleaning process is then performed.

Referring to FIG. 1C, an etch process is performed in a polysilicon layer chamber using the hard mask layer 112 that remains as a mask. Accordingly, the polysilicon layer 104, the tunnel oxidization layer 102 and the semiconductor substrate 100 are sequentially stripped by the etch process thereby forming trenches 118. At this time, though the anti-reflection layer 110 is stripped, it remains on the nitride layer 106 to the extent that the nitride layer 106 will not be lost. The polysilicon chamber may include suitable etch equipment, such as Reactive Ion Etching (RIE), Magnetically Enhanced Reactive Ion Etch (ME-RIE), Inductively Coupled Plasma (ICP), Electron Cyclotron Resonance (ECR) or Helicon, regardless of a plasma type.

The polysilicon layer 104 is preferably etched in the ICP type etch equipment by using a pressure of 3 mT to 1000 mT, source and bias powers of 50 W to 1000 W, and any of HBr gas, He gas, Cl₂ gas, O₂ gas, or a mixture thereof. The tunnel oxidization layer 102 is preferably etched in ICP type etch equipment by using a pressure of 3 mT to 1000 mT, source and bias powers of 50 W to 1000 W, and any of CF₄ gas, CHF₃ gas, Ar gas, O₂ gas, or a mixture thereof. The semiconductor substrate 100 is preferably etched in ICP type etch equipment by using a pressure of 3 mT to 1000 mT, source and bias powers of 50 W to 1000 W, and any of Cl₂ gas, HBr gas, O₂ gas, CF₄ gas, or a mixture thereof.

As described above, in the ICP type polysilicon layer chamber, CHF₃ and Ar gases, which can reduce the source and bias powers and are not frequently used in the polysilicon layer chamber, may be used according to the invention. Accordingly, the etch ratio of the oxidization layer can be increased and the etch ratio of the semiconductor substrate 100 can be decreased, enabling the tunnel oxidization layer 102 to be etched effectively. As described above, the polysilicon layer 104, the tunnel oxidization layer 102, and the semiconductor substrate 100 are consecutively etched in one equipment. It is therefore possible to shorten the TAT and minimize equipment investment.

As described above, according to the invention, the polysilicon layer, the tunnel oxidization layer and the semiconductor substrate are consecutively etched in the polysilicon layer chamber. Accordingly, an etch step and a cleaning step can be reduced, the TAT can be shortened, and additional equipment investment is not required. It is therefore possible to improve the productivity and save the cost.

Furthermore, a probability that particles may occur is reduced due to a reduction of the etch step. Accordingly, yield can be improved at the time of mass-production.

Although the foregoing description has been made with reference to various embodiments, changes and modifications may be made by those of ordinary skill in the art without departing from the spirit and scope of the invention.

What is claimed is:

1. A method of manufacturing a NAND flash memory device, comprising the steps of:
forming a tunnel oxidization layer, a polysilicon layer, a hard mask layer, an organic anti-reflection layer, and a photoresist pattern on a semiconductor substrate;
etching the organic anti-reflection layer and the hard mask layer using the photoresist pattern as a mask; and
consecutively etching the polysilicon layer, the tunnel oxidization layer, and the semiconductor substrate in one chamber using the hard mask layer as a mask, thereby forming a trench.

2. The method of claim 1, wherein the hard mask layer comprises a nitride layer, an oxidization layer, and an anti-reflection layer.

3. The method of claim 2, comprising forming the anti-reflection layer using SiON.

4. The method of claim 1, further comprising the step of stripping the photoresist pattern after etching the hard mask layer.

5. The method of claim 4, comprising stripping the organic anti-reflection layer simultaneously when stripping the photoresist pattern.

6. The method of claim 1, wherein the chamber is a Reactive Ion Etching (RIE) chamber, a Magnetically Enhanced Reactive Ion Etch (ME-RIE) chamber, an Inductively Coupled Plasma (ICP) chamber, an Electron Cyclotron Resonance (ECR) chamber, or Helicon equipment.

7. The method of claim 1, comprising etching the polysilicon layer by using a pressure of 3 mT to 1000 mT, source and bias powers of 50 W to 1000 W, and a gas selected from the group consisting of HBr gas, He gas, Cl₂ gas, O₂ gas, and mixtures thereof.

8. The method of claim 1, comprising etching the tunnel oxidization layer by using a pressure of 3 mT to 1000 mT, source and bias powers of 50 W to 1000 W, and a gas selected from the group consisting of CF₄ gas, CHF₃ gas, Ar gas, O₂ gas, and mixtures thereof.

9. The method of claim 1, comprising etching the semiconductor substrate by using a pressure of 3 mT to 1000 mT, source and bias powers of 50 W to 1000 W, and a gas selected from the group consisting of Cl₂ gas, HBr gas, O₂ gas, CF₄ gas, and mixtures thereof.

10. A method of manufacturing a NAND flash memory device, comprising the steps of:
forming a tunnel oxidization layer, a polysilicon layer, a hard mask layer, an organic anti-reflection layer, and a photoresist pattern on a semiconductor substrate;
etching the organic anti-reflection layer and the hard mask layer using the photoresist pattern as a mask;
etching the polysilicon layer within a polysilicon layer chamber using the hard mask layer as a mask;
etching the tunnel oxidization layer within the polysilicon layer chamber after etching the polysilicon layer, comprising etching the tunnel oxidization layer using CHF₃ and Ar gas with source and bias powers being reduced and an oxide layer etch ratio being increased; and
etching the semiconductor substrate within the polysilicon layer chamber after etching the tunnel oxidization layer, thus forming a trench.
